(19) United States
(12) Patent Application Publication
(10) Pub. No.: US 2006/0192207 A1
(43) Pub. Date: Aug. 31, 2006

(54) Nitride semiconductor light emitting device

(75) Inventors: Hyun Wook Shim, Suwon (KR); Jong Hak Won, Suwon (KR); Jin Sub Park, Suwon (KR); Joong Seo Kang, Yongin (KR); Hyun Jin Lee, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/247,152

(22) Filed: Oct. 12, 2005

(30) Foreign Application Priority Data
Feb. 28, 2005 (KR) 10-2005-16524

(51) Int. Cl. H01L 33/00

(52) U.S. Cl. 257/79

(57) ABSTRACT

Provided is a nitride semiconductor light emitting device having enhanced output power and resistance to electrostatic discharge. The light emitting device comprises an n-side contact layer formed on a substrate, a current diffusion layer formed on the n-side contact layer, an active layer formed on the current diffusion layer, and a p-type clad layer formed on the active layer. The current diffusion layer is formed by alternately stacking at least one first InAlGaN layer having a higher electron concentration than that of the n-side contact layer and at least one second InAlGaN layer having a lower electron concentration than that of the n-side contact layer.

### RELATED APPLICATION

The present invention is based on, and claims priority from, Korean Application Number 2005-16524, filed Feb. 28, 2005, the disclosure of which is incorporated by reference herein in its entirety.

### BACKGROUND OF THE INVENTION

1. Field of the Invention

The present invention generally relates to a nitride semiconductor light emitting device, and, more particularly, to a nitride semiconductor light emitting device, designed to have a low operating voltage and an enhanced tolerance to electrostatic discharge (ESD) while providing enhanced light emitting efficiency.

2. Description of the Related Art

Recently, a III-V group nitride semiconductor, such as a gallium nitride (GaN) semiconductor, has been in the spotlight as an essential material for light emitting devices, such as light emitting diodes (LEDs), laser diodes (LDs), and the like, due to its excellent physical and chemical properties. In particular, LEDs or LDs manufactured using the III-V nitride semiconductor material, are mainly used for light emitting devices for emitting light in the green wavelength band, and are used as a light source for many applications, such as video display boards, illuminating apparatuses, etc. Generally, the III-V nitride semiconductor material comprises a GaN-based material having the formula InₓAl_{y}Ga_{(1-x-y)}N (where 0≦x≦1, 0≦y≦1, 0≦x+y≦1).

As shown in FIG. 1, a conventional nitride semiconductor light emitting device 10 comprises a GaN buffer layer 13, an n-type GaN clad layer 14, an InGaN/GaN active layer 16 having a single quantum-well or multi quantum-well structure, and a p-type GaN clad layer 18 sequentially stacked on a dielectric sapphire substrate 11 in this order. Some portions of the n-type GaN clad layer 14 and the p-type GaN clad layer 18 are exposed by mesa etching so as to allow an n-side electrode 24 to be formed on the exposed portion of the n-type GaN clad layer 14. Additionally, a transparent electrode layer 20 and a p-side electrode 22 are formed on the p-type GaN clad layer 18. Japanese Patent Laid-open Publication No. (Hei) 10-135514 discloses a nitride semiconductor light emitting device comprising an active layer having the multi quantum-well structure consisting of an undoped GaN barrier layer and an undoped InGaN well layer, and a clad layer having a larger band gap than that of the barrier layer.

However, in order to employ the nitride semiconductor light emitting device as a light source for outdoor video display boards or illuminating apparatuses, it is necessary to enhance optical power of the light emitting device. In particular, the nitride semiconductor LD should be enhanced so as to realize a lower threshold voltage while exhibiting more stable operating characteristics. Additionally, the nitride semiconductor LED should be enhanced so as to reduce heat generation through reduction of operating voltage V_{f} while enhancing reliability and life span thereof.

Since nitride semiconductor light emitting devices generally have a low tolerance to ESD, it is required to enhance tolerance to ESD. Nitride semiconductor LEDs/LDs can be broken by electrostatic discharge from a human or a foreign material when using or handling the LEDs/LDs. A variety of investigations have been conducted with the aim of developing technology to prevent ESD-induced damage to nitride light emitting devices. For example, U.S. Pat. No. 6,593,597 discloses technology for protecting a light emitting device from EDS by integrating an LED and a Schottky diode on an identical substrate and connecting them in parallel. Additionally, in order to enhance the tolerance to ESD, an approach of connecting the LED to a Zener diode in parallel has been suggested. However, these approaches complicate the manufacturing process of the light emitting device and increase manufacturing costs due to purchase and assembly of the Zener diode or formation of the Schottky junction.

### SUMMARY OF THE INVENTION

The present invention has been made in view of the above problems, and it is an object of the present invention to provide a nitride semiconductor light emitting device, which provides higher output power while having a lower operating voltage.

It is another object of the invention to provide the nitride semiconductor light emitting device which can realize an enhanced tolerance to ESD without additional devices for enhancing the tolerance to ESD.

In accordance with one aspect of the present invention, the above and other objects can be accomplished by the provision of a nitride semiconductor light emitting device, comprising: an n-side contact layer formed on a substrate; a current diffusion layer formed on the n-side contact layer; an active layer formed on the current diffusion layer; and a p-type clad layer formed on the active layer. The current diffusion layer may be formed by alternately stacking at least one first InAlGaN layer having a higher electron concentration than that of the n-side contact layer and at least one second InAlGaN layer having a lower electron concentration than that of the n-side contact layer.

The main characteristic of the invention is that the electron diffusion layer having a multilayer structure is formed between the n-side contact layer and the active layer. The electron diffusion layer is formed by alternately stacking the first InAlGaN layer having the higher electron concentration than that of the n-side contact layer and the second InAlGaN layer having the lower electron concentration than that of the n-side contact layer. As the electron diffusion layer of the multilayer structure is inserted into an n-side region, current can be more effectively diffused into the n-side region. Accordingly, the nitride semiconductor light emitting device of the invention has a lower operating voltage and enhanced light emitting efficiency.

The n-side contact layer may have an electron concentration of 1×10¹⁸ to 5×10¹⁸ cm⁻³. In this case, the first InAlGaN layer may have an electron concentration of 1×10²⁰ cm⁻³ or less, and the second InAlGaN layer may have an electron concentration of 1×10¹⁶ cm⁻³ or more. Preferably, the n-side contact layer has an electron concentration of 3×10¹⁸ to 5×10¹⁸ cm⁻³.

The current diffusion layer may comprise three or more InAlGaN layers consisting of the at least one first InAlGaN layer and the at least one second InAlGaN layer. Preferably, the current diffusion layer comprises four or more InAlGaN layers consisting of at least two first InAlGaN layers and at least two second InAlGaN layers. The plurality of first InAlGaN layers and a plurality of second InAlGaN layers are alternately stacked.

The nitride semiconductor light emitting device may further comprise an n-type InAlGaN clad layer between the current diffusion layer and the active layer. In this case, the n-type InAlGaN clad layer may have an electron concentration lower than that of the first InAlGaN layer and higher than that of the second InAlGaN layer. Preferably, the n-type InAlGaN clad layer has an electron concentration equal to or less than that of the n-side contact layer. Preferably, the n-type InAlGaN clad layer has an electron concentration of 5×10¹⁷ to 1×10¹⁸ cm⁻³.

The lowermost layer of the current diffusion layer may be the first InAlGaN layer having an electron concentration higher than that of the n-side contact layer. In this case, the uppermost layer of the current diffusion layer may be the second InAlGaN layer having an electron concentration lower than that of the n-side contact layer or the first InAlGaN layer having an electron concentration higher than that of the n-side contact layer.

The lowermost layer of the current diffusion layer may be the second InAlGaN layer having an electron concentration lower than that of the n-side contact layer. In this case, the uppermost layer of the current diffusion layer may be the first InAlGaN layer having an electron concentration higher than that of the n-side contact layer or the second InAlGaN layer having an electron concentration lower than that of the n-side contact layer.

The current diffusion layer may have a step-shaped electron concentration profile. Alternatively, the current diffusion layer may have a peak-shaped electron concentration profile having spike portions formed by delta doping.

At least one of the first and second InAlGaN layers may have a thickness equal to or less than a critical elastic thickness. Preferably, both of the first InAlGaN layer and the second InAlGaN layer have a thickness equal to or less than a critical elastic thickness. Preferably, at least one of the first and second InAlGaN layers has a thickness of 100 Å or less, and more preferably of 60 Å or less. The current diffusion layer may constitute a multilayer thin film having a super lattice structure.

Preferably, a Si-dopant is added to the n-side contact layer and the current diffusion layer corresponding to the n-side region, and an Mg-dopant is added to the p-type clad layer corresponding to a p-side region. More preferably, indium is added together with the Si-dopant to the n-side contact layer and the current diffusion layer. Further, more preferably, indium is added together with the Mg-dopant to the p-type clad layer.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view illustrating a conventional nitride semiconductor light emitting device;

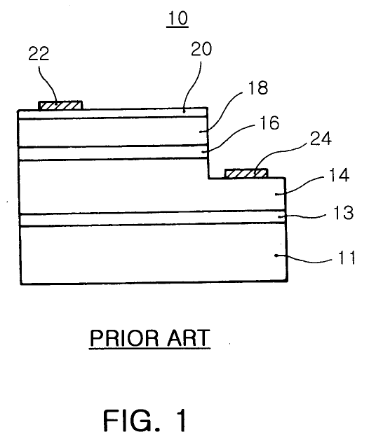

FIG. 2 is a cross-sectional view illustrating a nitride semiconductor light emitting device according to one embodiment of the present invention;

FIG. 3 is a cross-sectional view illustrating a nitride semiconductor light emitting device according to another embodiment of the present invention;

FIG. 4 is a partially cross-sectional view illustrating a current diffusion layer according to one embodiment of the present invention;

FIG. 5 is a graph schematically illustrating one example of an electron concentration profile of the current diffusion layer of FIG. 4;

FIG. 6 is a graph schematically illustrating another example of an electron concentration profile of the current diffusion layer of FIG. 4;

FIG. 7 is a partially cross-sectional view illustrating a current diffusion layer according to another embodiment of the present invention;

FIG. 8 is a graph schematically illustrating one example of an electron concentration profile of the current diffusion layer of FIG. 7;

FIG. 9 is a partially cross-sectional view illustrating a current diffusion layer according to yet another embodiment of the present invention; and

FIG. 10 is a graph schematically illustrating one example of an electron concentration profile of the current diffusion layer of FIG. 9.

### DESCRIPTION OF THE PREFERRED EMBODIMENTS

Preferred embodiments will now be described in detail with reference to the accompanying drawings. It should be noted that the embodiments of the invention can take various forms, and that the present invention is not limited to the embodiments described herein. The embodiments of the invention are described so as to enable those having an ordinary knowledge in the art to have a perfect understanding of the invention. Accordingly, shape and size of components of the invention are enlarged in the drawings for clear description of the invention. Like components are indicated by the same reference numerals throughout the drawings.

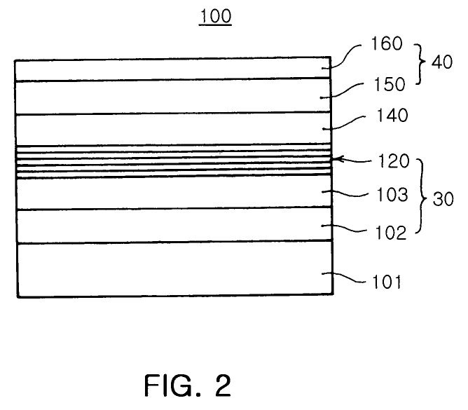

FIG. 2 is a cross-sectional view illustrating a nitride semiconductor light emitting device according to one embodiment of the invention. Referring to FIG. 2, the nitride semiconductor light emitting device 100 comprises an undoped GaN layer 102, an n-side contact layer 103, a current diffusion layer 120, an active layer 140, and a p-type clad layer 150 sequentially formed on a substrate 101 composed of sapphire or the like. The light emitting device 100 further comprises a p-side contact layer 160 on the p-type clad layer 150.

The undoped GaN layer 102, n-side contact layer 103, and current diffusion layer 120 constitute an n-side region 30 of the light emitting device 100. The n-side contact layer 103 and the current diffusion layer 120 are composed of n-type InAlGaN, which is doped with an n-type dopant. The n-type dopant includes Si, Ge and Sn, and preferably, Si.

The p-type clad layer 150 and p-side contact layer 160 constitute a p-side region 40, and are composed of p-type InAlGaN, which is doped with a p-type dopant. The p-type dopant includes Mg, Zn, and Be, and preferably Mg. The active layer 40 interposed between the n-side region 30 and the p-side region 40 may have a multi-quantum well structure of, for example, InGaN/GaN.

The current diffusion layer 120 is interposed between the n-side contact layer 103 and the active layer 140. The current diffusion layer 120 alternately comprises an InAlGaN layer having a higher electron concentration than that of the n-side contact layer 103, and an InAlGaN layer having a lower electron concentration than that of the n-side contact layer 103. The current diffusion layer 120 may comprise at least one InAlGaN layer of the higher electron concentration, and at least one InAlGaN layer of the lower electron concentration. Preferably, the current diffusion layer 120 comprises three or more InAlGaN layers. More preferably, the current diffusion layer 120 comprises four or more InAlGaN layers consisting of at least two InAlGaN layers of the higher electron concentration, and at least two InAlGaN layers of the lower electron concentration. Most preferably, the current diffusion layer 120 has a super lattice structure, which is formed by alternately stacking a plurality of InAlGaN layers of the higher electron concentration, and a plurality of InAlGaN layers of the lower electron concentration.

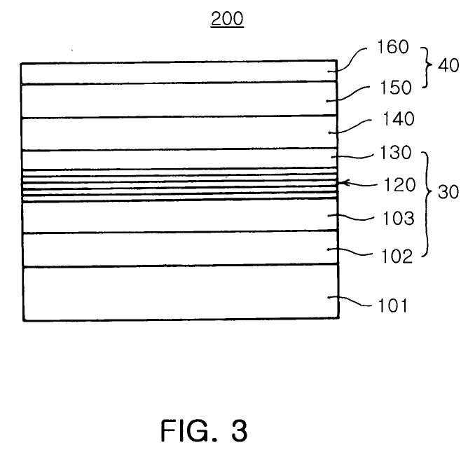

FIG. 3 is a cross-sectional view illustrating a nitride semiconductor light emitting device according to another embodiment of the invention. Referring to FIG. 3, the nitride semiconductor light emitting device 200 further comprises another n-type semiconductor layer, that is, an n-type clad layer 140 between a current diffusion layer 120 and an active layer 140. The electron concentration of the n-type clad layer 140 is between that of the InAlGaN layers of the higher electron concentration and that of the InAlGaN layers of the lower electron concentration. Particularly, the n-type clad layer 140 preferably has an electron concentration equal to or less than that of the n-side contact layer 103. Preferably, the n-type InAlGaN clad layer has an electron concentration of 5×10¹⁷ to 1×10¹⁸ cm⁻³.

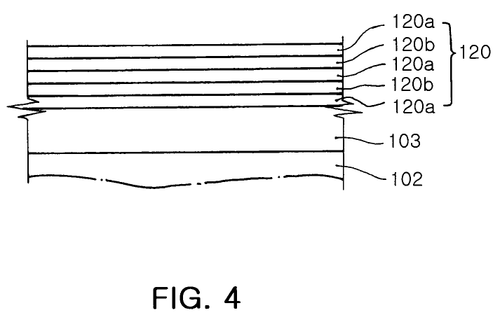

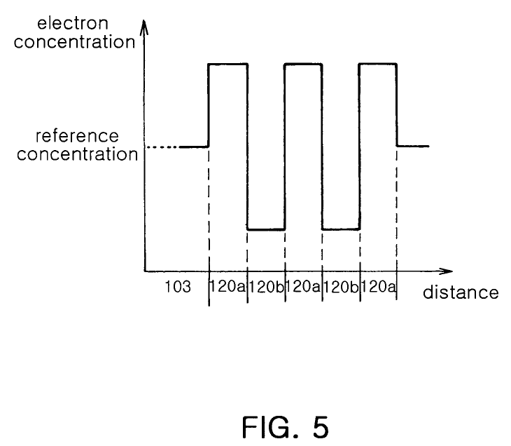

FIG. 4 is a partially cross-sectional view illustrating a current diffusion layer 120 according to one embodiment of the invention, and FIG. 5 is a graph schematically illustrating one example of an electron concentration profile of the current diffusion layer of FIG. 4. Referring to FIG. 4, the current diffusion layer 120 is formed on the undoped GaN layer 102 and the n-side contact layer 103. As shown in FIGS. 3 and 4, the current diffusion layer 120 is formed by alternately stacking first InAlGaN layers 120a having a higher electron concentration than that of the n-side contact layer 103 and second InAlGaN layers 120b having a lower electron concentration than that of the n-side contact layer 103. In particular, as shown in FIG. 5, the current diffusion layer 120 may have a step-shaped electron concentration profile. As a result, the electron concentration is rapidly varied near interfaces between the first InAlGaN layers 120a and the second InAlGaN layers 120b. In FIG. 5, a reference concentration is the electron concentration of the n-side contact layer 103.

The n-side contact layer 103 preferably has an electron concentration of 1×10¹⁸ to 5×10¹⁶ cm⁻³ and more preferably, of 3×10¹⁸ to 5×10¹⁸ cm⁻³. Moreover, preferably, each of the first InAlGaN layers has an electron concentration of 1×10²⁰ cm⁻³ or less, and each of the second InAlGaN layers have an electron concentration of 1×10¹⁶ cm⁻³ or more.

When the n-side contact layer 103 and the current diffusion layer 120 have an electron concentration of 1×10¹⁸ or more, sufficient carrier mobility can be ensured. Meanwhile, the electron concentration can be remarkably increased through higher concentration doping in order to further reduce resistivity of the n-side contact layer 103 and the current diffusion layer 120. However, when the doping concentration is significantly high, crystallinity of the n-side contact layer 103 and the current diffusion layer 120 can be deteriorated. With regard to this, crystal defects caused by higher electron concentration (or doping concentration) in the current diffusion layer 120 can be overcome by forming the current diffusion layer 120 such that at least one of the first InAlGaN layer 120a and the second InAlGaN layer 120b has a thickness equal to or less than a critical elastic thickness. In this manner, when the at least one of the first InAlGaN layer 120a and the second InAlGaN layer 120b has a thickness equal to or less than the critical elastic thickness, propagation of the crystal defects can be prevented, thereby forming a nitride semiconductor layer having a positive crystallinity. Preferably, both of the first InAlGaN layer 120a and the second InAlGaN layer 120b have a thickness equal to or less than a critical elastic thickness. For example, the first InAlGaN layer and the second InAlGaN layer preferably have a thickness of 100 Å or less, and more preferably of 60 Å or less. As a result, each of the first InAlGaN layers 120a has a higher electron concentration above 1×10¹⁹ cm⁻³, and has a low resistivity.

With low crystal defects, when the first InAlGaN layers 120a of the higher electron concentration are formed adjacent to the second InAlGaN layers 120b of the lower electron concentration, respectively, charge carriers (electrons) passing through the current diffusion layer 120 are diffused into adjacent regions due to the higher resistance of the second InAlGaN layers 120b (particularly, in a lateral direction). In this manner, as the electrons are diffused in the current diffusion layer 120, an operating voltage Vf of the light emitting device is lowered, and light emitting efficiency is enhanced due to an increase of a light emitting area, thereby increasing optical power.

Moreover, since the second InAlGaN layer 120b of the lower electron concentration interposed between the first InAlGaN layers 120a of the higher electron concentration has a relatively higher permittivity, a multilayer structure of first InAlGaN layer 120a/second InAlGaN layer 120b/first InAlGaN layer 120a can act as a kind of capacitor. Thus, the multilayer structure of the capacitor can protect the light emitting device from rapid surge voltage or electrostatic discharge, thereby enhancing electrostatic discharge resistance of the light emitting device.

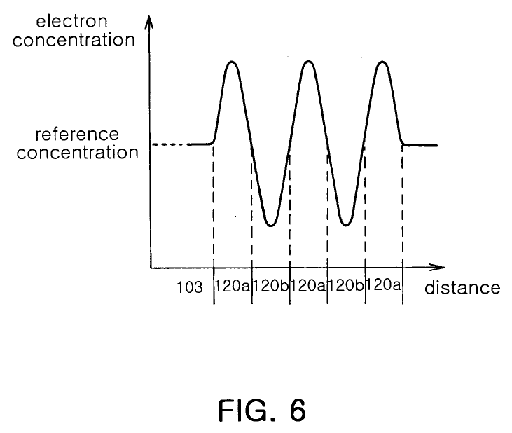

In addition to the step-shaped electron concentration profile as shown in FIG. 5, the current diffusion layer 120 may have other electron concentration profiles. FIG. 6 is a graph schematically illustrating another example of an electron concentration profile of the current diffusion layer 120 of FIG. 4. Referring to FIG. 6, the electron concentration profile of the current diffusion layer may have peak-shaped spike portions. The electron concentration profile having the peak-shaped spike portions can be realized by delta doping.

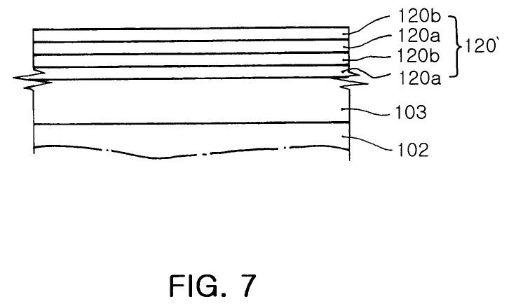

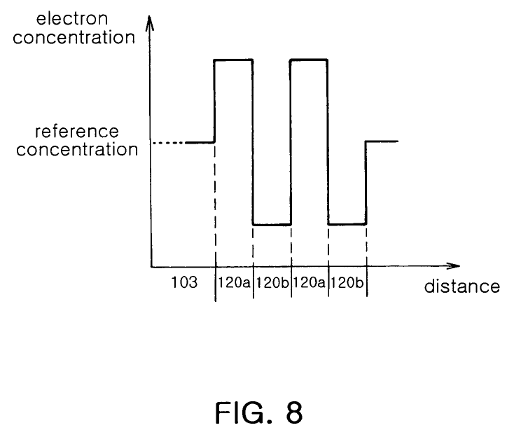

FIG. 7 is a partially cross-sectional view illustrating a current diffusion layer according to another embodiment of the invention, and FIG. 8 is a graph schematically illustrating one example of an electron concentration profile of the current diffusion layer of FIG. 7. As shown in FIGS. 7 and 8, as with the current diffusion layer 120 of FIG. 4, the lowermost layer of a current diffusion layer 120′ is a first InAlGaN layer 120a of a higher electron concentration. However, unlike the current diffusion layer 120 of FIG. 4, the uppermost layer of the current diffusion layer 120′ is a second InAlGaN layer 120b of a lower electron concentration. As such, the uppermost layer of the current diffusion layer 120 or 120′ may be either the first InAlGaN layer 120a or the second InAlGaN layer 120a.

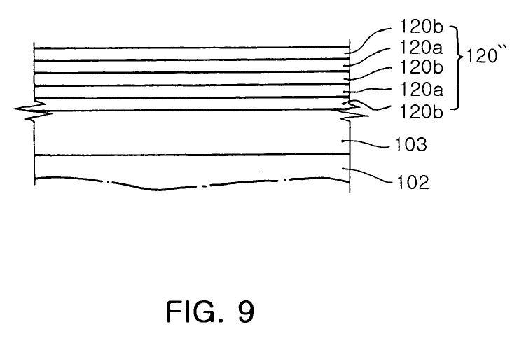

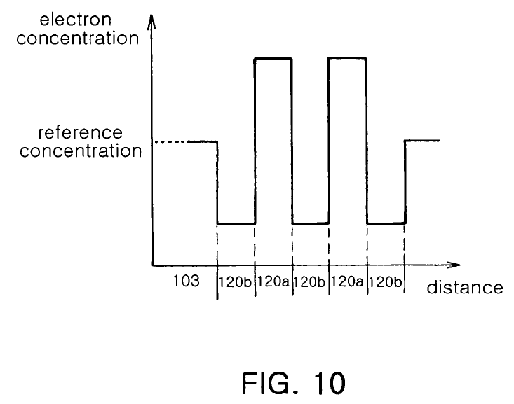

FIG. 9 is a partially cross-sectional view illustrating a current diffusion layer according to yet another embodiment of the present invention, and FIG. 10 is a graph schematically illustrating one example of an electron concentration profile of the current diffusion layer of FIG. 9. As shown in FIGS. 9 and 10, unlike the current diffusion layers 120 and 120′ of FIGS. 4 and 7, the lowermost layer of a current diffusion layer 120″ is a second InAlGaN layer 120b of a lower electron concentration. In this case, as shown in FIGS. 9 and 10, the uppermost layer of the current diffusion layer 120″ can be the second InAlGaN layer 120b of the lower electron concentration. However, the uppermost layer of the current diffusion layer 120″ can be a first InAlGaN layer 120a of a higher electron concentration (not shown).

Indium is preferably added together with the Si-dopant to the n-side contact layer 103 and the current diffusion layer 120 corresponding to the n-side region 30 (see FIG. 2). Added indium acts as a surfactant in the n-side region 30, thereby lowering activation energy of the Si-dopant. Thus, a ratio of Si-dopnat practically creating the charge carriers (electrons) is increased, and the crystallinity of the n-side region 30 is further enhanced. As a result, the operating voltage of the light emitting device can be further lowered.

Moreover, indium is also added together with the Mg-dopant to the p-type clad layer 150 and the p-side contact layer 160 corresponding to the p-side region 40 (see FIG. 2). Added indium acts as a surfactant in the p-side region 30, thereby lowering activation energy of the Mg-dopant. As a result, the operating voltage of the light emitting device can be further lowered.

As apparent from the above description, according to the invention, the electron diffusion layer of the multilayer structure is formed between the n-side contact layer and the active layer, in which the electron diffusion layer is formed by alternately stacking first InAlGaN layers of a higher electron concentration and second InAlGaN layers of a lower electron concentration, thereby enhancing the output power of the nitride semiconductor light emitting device while lowering the operating voltage thereof.

Furthermore, the multilayer structure of the first InAlGaN layer/second InAlGaN layer/InAlGaN layer in the current diffusion layer acts as a capacitor, and enhances tolerance to ESD of the light emitting device, thereby realizing highly reliable light emitting devices.

It should be understood that the embodiments and the accompanying drawings have been described for illustrative purposes and the present invention is limited only by the following claims. Further, those skilled in the art will appreciate that various modifications, additions, and substitutions are allowed without departing from the scope and spirit of the invention as set forth in the accompanying claims.

What is claimed is:

1. A nitride semiconductor light emitting device, comprising:
an n-side contact layer formed on a substrate;
a current diffusion layer formed on the n-side contact layer;
an active layer formed on the current diffusion layer; and
a p-type clad layer formed on the active layer, wherein the current diffusion layer is formed by alternately stacking at least one first InAlGaN layer having a higher electron concentration than that of the n-side contact layer and at least one second InAlGaN layer having a lower electron concentration than that of the n-side contact layer.

2. The light emitting device as set forth in claim 1, wherein the n-side contact layer has an electron concentration of 1×10¹⁸ to 5×10¹⁸ cm⁻³.

3. The light emitting device as set forth in claim 2, wherein the first InAlGaN layer has an electron concentration of 1×10²⁰ cm⁻³ or less, and the second InAlGaN layer has an electron concentration of 1×10¹⁶ cm⁻³ or more.

4. The light emitting device as set forth in claim 2, wherein the n-side contact layer has an electron concentration of 3×10¹⁸ to 5×10¹⁸ cm⁻³.

5. The light emitting device as set forth in claim 1, wherein the current diffusion layer comprises three or more InAlGaN layers consisting of the at least one first InAlGaN layer and the at least one second InAlGaN layer.

6. The light emitting device as set forth in claim 5, wherein the current diffusion layer comprises four or more InAlGaN layers consisting of at least two first InAlGaN layers and at least two second InAlGaN layers.

7. The light emitting device as set forth in claim 1, further comprising:
an n-type InAlGaN clad layer between the current diffusion layer and the active layer.

8. The light emitting device as set forth in claim 7, wherein the n-type InAlGaN clad layer has an electron concentration lower than that of the first InAlGaN layer and higher than that of the second InAlGaN layer.

9. The light emitting device as set forth in claim 7, wherein the n-type InAlGaN clad layer has an electron concentration equal to or less than that of the n-side contact layer.

10. The light emitting device as set forth in claim 7, wherein the n-type InAlGaN clad layer has an electron concentration of 5×10¹⁷ to 1×10¹⁸ cm⁻³.

11. The light emitting device as set forth in claim 1, wherein the lowermost layer of the current diffusion layer is the first InAlGaN layer.

12. The light emitting device as set forth in claim 11, wherein the uppermost layer of the current diffusion layer is the second InAlGaN layer.

13. The light emitting device as set forth in claim 11, wherein the uppermost layer of the current diffusion layer is the first InAlGaN layer.

14. The light emitting device as set forth in claim 1, wherein the lowermost layer of the current diffusion layer is the second InAlGaN layer.

15. The light emitting device as set forth in claim 14, wherein the uppermost layer of the current diffusion layer is the first InAlGaN layer.

16. The light emitting device as set forth in claim 14, wherein the uppermost layer of the current diffusion layer is the second InAlGaN layer.

17. The light emitting device as set forth in claim 1, wherein the current diffusion layer has a step-shaped electron concentration profile.

18. The light emitting device as set forth in claim 1, wherein the current diffusion layer has a peak-shaped electron concentration profile having spike portions formed by delta doping.

19. The light emitting device as set forth in claim 1, wherein at least one of the first and second InAlGaN layers has a thickness equal to or less than a critical elastic thickness.

20. The light emitting device as set forth in claim 1, wherein at least one of the first and second InAlGaN layers has a thickness of 100 Å or less.

21. The light emitting device as set forth in claim 1, wherein at least one of the first and second InAlGaN layers has a thickness of 60 Å or less.

22. The light emitting device as set forth in claim 1, wherein the current diffusion layer constitutes a multilayer thin film of a super lattice structure.

23. The light emitting device as set forth in claim 1, wherein a Si-dopant is added to the n-side contact layer and the current diffusion layer.

24. The light emitting device as set forth in claim 23, wherein indium is further added to the n-side contact layer and the current diffusion layer.

25. The light emitting device as set forth in claim 1, wherein a Mg-dopant is added to the p-type clad layer.

26. The light emitting device as set forth in claim 25, wherein indium is further added to the p-type clad layer.
